(19) United States
(12) Patent Application Publication
(10) Pub. No.: US 2019/0333735 A1
(43) Pub. Date: Oct. 31, 2019

(54) PLASMA SOURCE AND PLASMA PROCESSING APPARATUS

(71) Applicant: EMD CORPORATION, Yasu-shi, Shiga (JP)

(72) Inventor: Akinori EBE, Kyoto-shi (JP)

(73) Assignee: EMD Corporation, Yasu-shi, Shiga (JP)

(21) Appl. No.: 16/312,424

(22) PCT Filed: Jun. 16, 2017
(86) PCT No.: PCT/JP2017/022321

§ 371 Date: Dec. 21, 2018

(30) Foreign Application Priority Data
Jun. 24, 2016 (JP) 2016-125618

(51) Int. Cl. H01J 37/32; C23C 16/505

(52) U.S. Cl. CPC H01J 37/3211; C23C 16/505; H01J 37/3244; H01J 2237/332; H01J 2237/0473; H01J 2237/334; H01J 37/32541

(57) ABSTRACT

A plasma source which is capable of supplying a plasma processing space with plasma in a state where gas is sufficiently ionized is a device for supplying plasma to a plasma processing space in which a process using the plasma is performed, and includes: a plasma generation chamber; an opening that allows the plasma generation chamber to communicate with the plasma processing space; a radio-frequency antenna that is a coil of less than one turn provided in a position where a radio-frequency electromagnetic field having predetermined strength required to generate plasma is able to be generated in the plasma generation chamber; voltage application electrodes in a position close to the opening in the plasma generation chamber; and a gas supply unit (pipe) that supplies plasma source gas to a position closer to the side opposite to the opening than the voltage application electrodes in the plasma generation chamber.

### TECHNICAL FIELD

The present invention relates to a plasma source for supplying plasma to a processing chamber in a deposition processor, an etching processor, etc. and a plasma processing apparatus using the plasma source.

### BACKGROUND ART

A general plasma processing apparatus performs processes, such as deposition, physical etching, and chemical etching, on a surface of a substrate to be processed by introducing gas (hereinafter, referred to as “plasma source gas”) into a processing chamber in which the substrate to be processed has been set, and forming a radio-frequency electromagnetic field in the processing chamber to turn the gas into plasma, and then causing dissociated gas molecules to enter the substrate to be processed.

Patent Literature 1 discloses an apparatus provided with a processing vessel (a processing chamber) and a plasma formation box (a plasma generation chamber) that communicates with the processing vessel through an opening and has a smaller capacity than the processing vessel, and provided with an inductively coupled radio-frequency antenna around the plasma formation box, and provided with a gas supply means to supply plasma source gas into the plasma formation box. This apparatus performs a process using plasma in the processing vessel by generating the plasma in the plasma formation box and supplying the plasma into the processing vessel through the opening. By generating plasma in the plasma formation box whose capacity is smaller than the processing vessel in this way, the energy efficiency of a radio-frequency electromagnetic field is enhanced as compared with a case of generating plasma in the processing vessel.

A set of the plasma formation box, the radio-frequency antenna, and the gas supply means according to Patent Literature 1 serves as a source for supplying plasma to the processing vessel. In this specification, such a source for supplying plasma to a processing vessel (a processing chamber) is referred to as a “plasma source”.

### CITATION LIST

### Patent Literature

Patent Literature 1: JP 2009-076876 A

### SUMMARY OF INVENTION

### Technical Problem

However, in the apparatus according to Patent Literature 1, not only plasma but also a portion of gas that has not yet been turned into plasma in the plasma formation box flow into the processing vessel through the opening. The gas that has entered the processing vessel can scarcely be subjected to the radio-frequency electromagnetic field from the radio-frequency antenna provided around the plasma formation box, and thus cannot be turned into plasma.

An issue to be resolved by the present invention is to provide a plasma source capable of supplying a processing vessel or a processing chamber with plasma in a state where gas is sufficiently ionized and a plasma processing apparatus using the plasma source.

### Solution to Problem

A plasma source according to the present invention made to resolve the above-described issue is a device for supplying plasma to a plasma processing space in which a process using the plasma is performed, and includes:

a) a plasma generation chamber;

b) an opening that allows the plasma generation chamber to communicate with the plasma processing space;

c) a radio-frequency antenna that is a coil of less than one turn provided in a position where a radio-frequency electromagnetic field having predetermined strength required to generate plasma is able to be generated in the plasma generation chamber;

d) voltage application electrodes provided in a position close to the opening in the plasma generation chamber; and

e) a gas supply unit that supplies plasma source gas to a position closer to a side opposite to the opening than the voltage application electrodes in the plasma generation chamber.

By using a coil of less than one turn as the radio-frequency antenna, the plasma source according to the present invention can reduce inductance of the radio-frequency antenna as compared with a coil of one or more turns, and can suppress loss of radio-frequency power and efficiently use energy for generation of plasma. Accordingly, gas molecules supplied from the gas supply unit into the plasma generation chamber are efficiently ionized and turned into plasma. Then, by applying a voltage between the voltage application electrodes, ionization of the gas molecules that have been supplied from the gas supply unit close to the side opposite to the opening and reached between the voltage application electrodes is enhanced, and thus it is possible to prevent gas that has not yet been turned into plasma from flowing into the plasma processing space through the opening.

The plasma source according to the present invention has an advantage of enhancing the ionization of the gas molecules, and also has an advantage that the plasma is easily ignited by the voltage applied between the voltage application electrodes. In a case of utilizing only this advantage, after the plasma is ignited, the application of the voltage between the voltage application electrodes may be stopped, or the voltage may be lowered.

As the voltage applied to the voltage application electrodes, a radio-frequency voltage is more desirable than a direct current voltage. By using the radio-frequency voltage, the ionization of the gas molecules can be enhanced, and the plasma can be ignited even at a low process pressure.

To generate a strong radio-frequency electromagnetic field in the plasma generation chamber, it is possible to provide a protection member made of a material resistant to plasma around the radio-frequency antenna and to provide the radio-frequency antenna covered with the protection member in the plasma generation chamber. If the radio-frequency antenna is provided outside the plasma generation chamber, the radio-frequency electromagnetic field in the plasma generation chamber is weak; however, there is no need to use the protection member, and the configuration can be simplified. Alternatively, by providing the radio-frequency antenna inside a wall that separates the plasma generation chamber from the outside, radio-frequency electromagnetic field of an adequate strength can be generated in the plasma generation chamber while preventing the radio-frequency antenna from being exposed to plasma.

The frequency of the radio-frequency current introduced into the radio-frequency antenna may not be limited to a particular range. The frequency can be set to 13.56 kHz typically used in commercially available radio-frequency power sources. When a radio-frequency voltage is applied to the voltage application electrodes, its frequency may not be limited to a particular range; however, it is desirable that the frequency be high enough so that the ionization may continue even if the voltage is low. In terms of being easy to handle and being easily discharged, the frequency of the radio-frequency voltage is desirably in the VHF band, that is 10 MHz to 100 MHz.

The plasma source according to the present invention can include an acceleration electrode having a hole; the acceleration electrode may be provided outside the plasma generation chamber in a position facing the opening, or inside the plasma generation chamber in a position closer to the side of the opening than the voltage application electrodes. According to this configuration, it can be used as an ion source that irradiates an object to be processed set in the plasma processing space (i.e. outside the plasma source) with cations. Concretely describing, a positive potential is applied to the acceleration electrode with an object to be processed or an object holder grounded, and thus cations generated through ionization of gas molecules in the plasma generation chamber pass through the hole of the acceleration electrode and are accelerated toward the object. The number of holes provided on the acceleration electrode may be only one, or may be multiple.

A plasma processing apparatus according to the present invention includes the plasma source and a plasma processing chamber whose inside is the plasma processing space.

### Advantageous Effects of Invention

A plasma source according to the present invention can supply a plasma processing space with plasma in a state where gas is sufficiently ionized.

### BRIEF DESCRIPTION OF DRAWINGS

FIG. 1 is a cross-sectional view showing an embodiment of a plasma source according to the present invention.

FIG. 2A is a perspective view, FIG. 2B is a cross-sectional view parallel to the front, and FIG. 2C is a cross-sectional view parallel to the side that show an example of the plasma source according to the present invention using a plurality of radio-frequency antennas.

FIG. 3 is a graph showing experimental data on ion saturation current density to process pressure.

FIG. 4 is a graph showing experimental data on ion saturation current density to radio-frequency power of the radio-frequency antenna.

FIG. 5 is a cross-sectional view showing an embodiment of a plasma processing apparatus according to the present invention.

FIG. 6 is a cross-sectional view showing a modification example of the plasma source in the present embodiment.

FIG. 7 is a partial enlarged cross-sectional view showing another modification example of the plasma source in the present embodiment.

### DESCRIPTION OF EMBODIMENTS

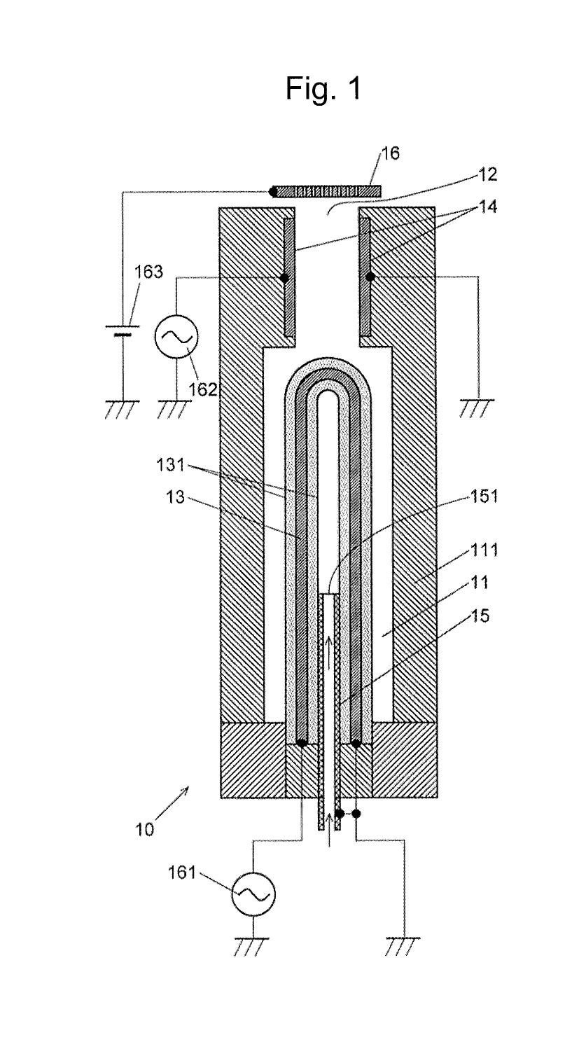

Respective embodiments of a plasma source and a plasma processing apparatus according to the present invention will be described with FIGS. 1 to 7.

As shown in FIG. 1, a plasma source 10 in the present embodiment includes a plasma generation chamber 11, an opening 12, a radio-frequency antenna 13, voltage application electrodes 14, a gas supply pipe 15, and an acceleration electrode 16.

The plasma generation chamber 11 is a space covered with a wall 111 including a dielectric, and the radio-frequency antenna 13 and one end of the gas supply pipe 15 are disposed inside the plasma generation chamber 11. The opening 12 is provided on the wall 111 of the plasma generation chamber, and has a slit-like shape viewed from above in FIG. 1. The outside of the opening 12 viewed from the plasma generation chamber 11 corresponds to the above-described plasma processing space.

The radio-frequency antenna 13 is a linear conductor bent into a U-shape, and corresponds to a coil of less than one turn. Both ends of the radio-frequency antenna 13 are mounted to the wall 111 of the plasma generation chamber 11 that faces the opening 12. The periphery of the radio-frequency antenna 13 is covered with a dielectric protection tube 131. The protection tube 131 is provided to protect the radio-frequency antenna 13 from plasma generated in the plasma generation chamber 11 as will be described later. One end of the radio-frequency antenna 13 is connected to a first radio-frequency power source 161, and the other end is grounded. The first radio-frequency power source 161 supplies the radio-frequency antenna 13 with 100 to 1000 W of radio-frequency power at a frequency of 13.56 MHz.

Of the wall 111 of the plasma generation chamber 11, a portion corresponding to an inner wall surface of the opening 12 is provided with a pair of the voltage application electrodes 14. These voltage application electrodes 14 are provided so as to hold a space in the plasma generation chamber 11 near the opening 12 between them; one of the electrodes is connected to a second radio-frequency power source 162, and the other electrode is grounded. The second radio-frequency power source 162 supplies between the electrodes with 50 to 500 W of radio-frequency power at a frequency of 60 MHz.

The gas supply pipe 15 is a stainless steel pipe provided so as to penetrate the wall 111 of the plasma generation chamber 11 that faces the opening 12. A distal end 151 of the gas supply pipe 15 in the plasma generation chamber 11 is disposed inside the U-shape of the radio-frequency antenna 13, and is located on the side opposite to the opening 12 viewed from the voltage application electrodes 14. Plasma source gas is supplied into the plasma generation chamber 11 through this distal end 151. The gas supply pipe 15 is grounded. Examples of the plasma source gas supplied from the gas supply pipe 15 may include various gases such as deposition source gas, gas for generating ions used for chemical etching and physical etching, and gas for generating an ion beam.

On the outside of the plasma generation chamber 11, a grounded object holder (not shown) is disposed in a position facing the opening 12, and the acceleration electrode 16 is provided in a position between the opening 12 and the object holder and near the opening 12. It is to be noted that the object holder is not included in the plasma source 10, and a set of the plasma source 10 and the object holder constitutes the plasma processing apparatus. The acceleration electrode 16 is a tungsten plate-like member provided with a lot of (multiple) holes. Alternatively, a plate-like member made of molybdenum or carbon instead of tungsten may be used. The acceleration electrode 16 is connected with a direct-current power source 163 that applies a positive potential of 100 to 2000 V to the ground. This configuration allows a direct electric field that causes positive ions to be accelerated toward the side of the object holder to be formed between the acceleration electrode 16 and the object holder.

The operation of the plasma source 10 in the present embodiment is described. While supplying plasma source gas into the plasma generation chamber 11 through the distal end 151 of the gas supply pipe 15, the first radio-frequency power source 161 supplies the radio-frequency antenna 13 with radio-frequency power, and the second radio-frequency power source 162 supplies between the voltage application electrodes 14 with radio-frequency power. This ignites plasma in the plasma generation chamber 11, and ionizes molecules of the plasma source gas near the radio-frequency antenna 13, and thus plasma is generated, and the ionization of gas molecules in the plasma is enhanced between the voltage application electrodes 14. In the plasma generated in this way, positive ions and electrons exist. The generated plasma passes through the holes provided on the acceleration electrode 16 through the opening 12. Then, the acceleration electrode 16 is subjected to a positive potential applied to the ground by the direct-current power source 163, and thus the positive ions in the plasma are accelerated from the acceleration electrode 16 toward the object holder, and pass through the holes provided on the acceleration electrode 16 and are supplied to the plasma processing space.

The plasma source 10 in the present embodiment can generate an ion beam by accelerating positive ions using the acceleration electrode 16 as described above. Such an ion beam can be suitably used for processes, such as etching of an object to be processed and ion implantation, by setting the object in the object holder.

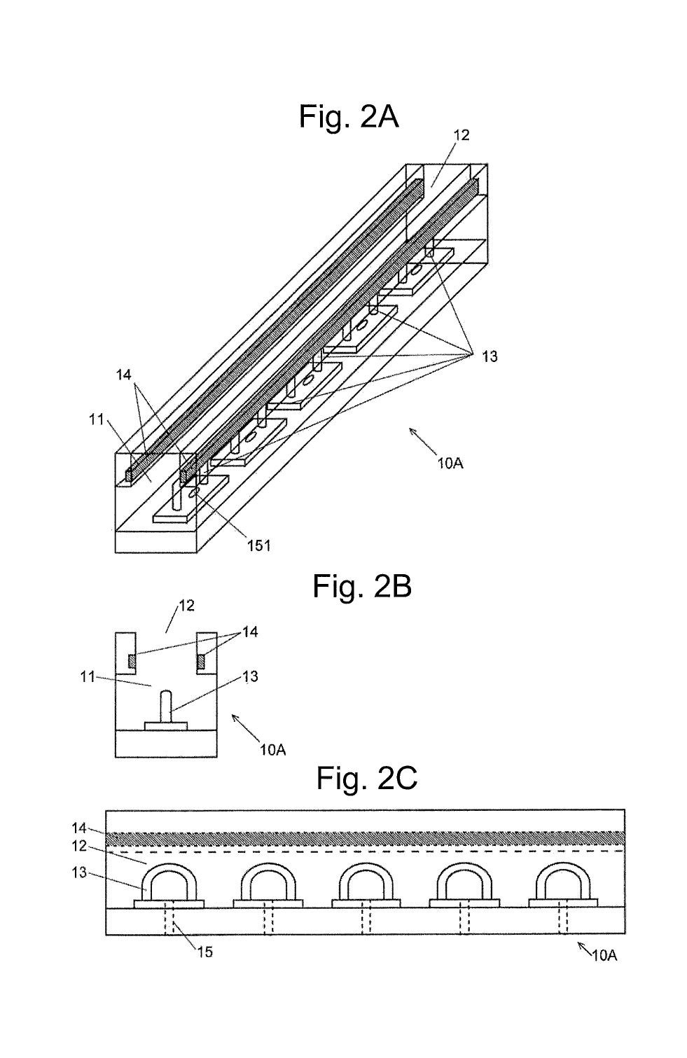

The number of radio-frequency antennas 13 is not limited to one; for example, multiple radio-frequency antennas 13 may be provided as shown in FIGS. 2A-2C. In a plasma source 10A shown in FIGS. 2A-2C, multiple radio-frequency antennas 13 (although the number of radio-frequency antennas 13 is not limited, five radio-frequency antennas 13 are depicted in FIGS. 2A-2C) are arranged along the slit of the opening 12. In the present embodiment, the U-shaped surface of the radio-frequency antenna 13 is directed parallel to the slit (that is, a normal direction of the U-shaped surface of the radio-frequency antenna 13 is perpendicular to a longitudinal direction of the slit). However, the direction of the U-shaped surface is not limited to this example. As the voltage application electrodes 14, a pair of (two) electrodes extending along the longitudinal direction of the slit of the opening 12 is used. By using the multiple radio-frequency antennas 13 in this way, plasma can be supplied to a wide plasma processing space. It is to be noted that FIGS. 2A-2C do not illustrate the power sources. Furthermore, although not shown in FIGS. 2A-2C, an acceleration electrode may be provided as with the example of FIG. 1.

Results of experiments performed by using the plasma source 10 in the present embodiment are described below.

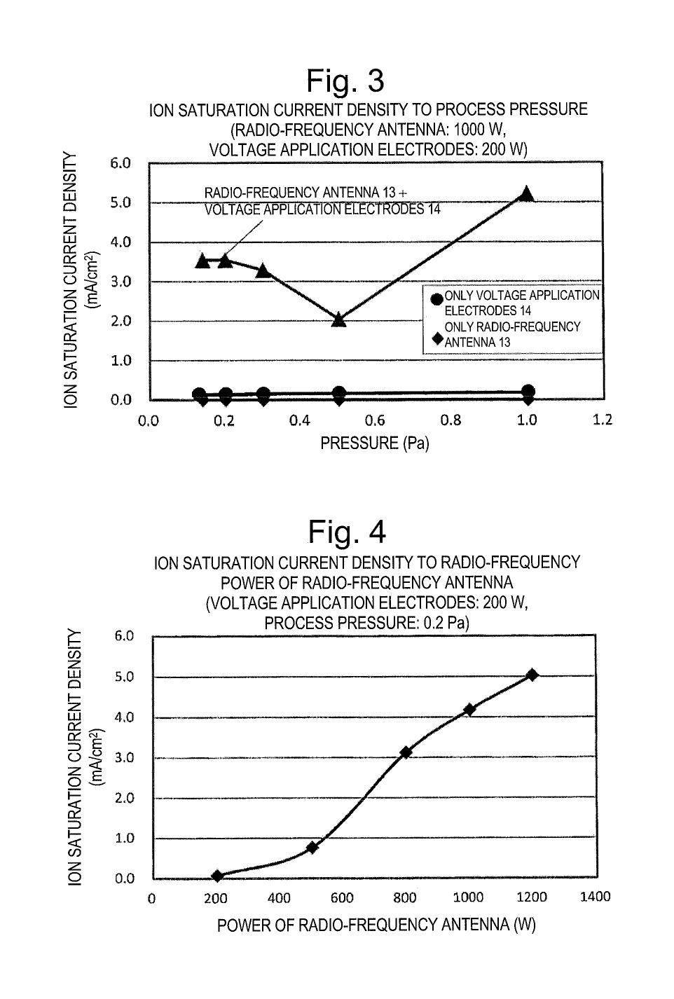

First, we measured respective ion saturation current densities of plasma generated at several process pressures, provided that radio-frequency power supplied to the radio-frequency antenna 13 was fixed at 1000 W (a frequency of 13.56 MHz), and radio-frequency power supplied to the voltage application electrodes 14 was fixed at 200 W (a frequency of 60 MHz). For comparison, we also performed similar experiments in a case where the supply of the radio-frequency power to the voltage application electrodes 14 was stopped and only the radio-frequency antenna 13 was supplied with the radio-frequency power (1000 W, 13.56 MHz) and a case where the supply of the radio-frequency power to the radio-frequency antenna 13 was stopped and only the voltage application electrodes 14 were supplied with the radio-frequency power (200 W, 60 MHz). FIG. 3 shows results of these experiments. The results of these experiments confirmed that at any pressure within a measurement range, when only either the radio-frequency antenna 13 or the voltage application electrodes 14 were supplied with the radio-frequency power, plasma could scarcely be generated, whereas when both the radio-frequency antenna 13 and the voltage application electrodes 14 were supplied with the radio-frequency power, plasma could be generated.

Next, we measured respective ion saturation current densities of plasma generated in several cases of different radio-frequency powers supplied to the radio-frequency antenna 13, provided that the radio-frequency power supplied to the voltage application electrodes 14 was fixed at 200 W (a frequency of 60 MHz), and the process pressure was fixed at 0.2 Pa (the minimum pressure in FIG. 3). FIG. 4 shows results of these experiments. The higher the radio-frequency power supplied to the radio-frequency antenna 13 was, the higher the ion saturation current density of plasma was. These results confirmed that the radio-frequency antenna 13 effectively worked for generation of plasma.

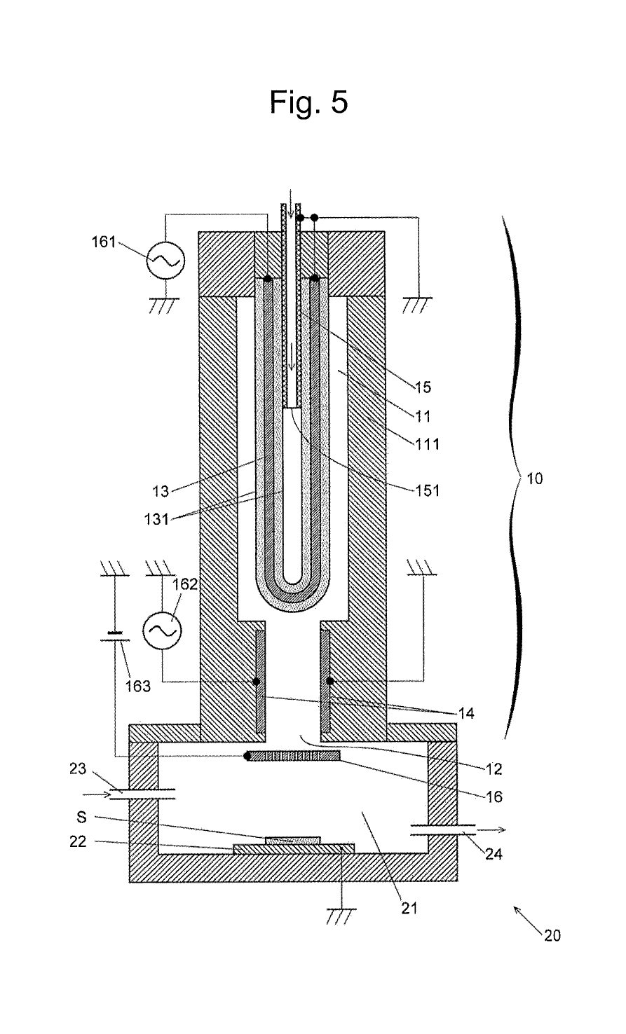

FIG. 5 shows the embodiment of the plasma processing apparatus according to the present invention. This plasma processing apparatus 20 includes: the above-described plasma source 10; a plasma processing chamber 21 whose internal space communicates with the opening 12 of the plasma source 10; an object stand 22 provided in the plasma processing chamber 21 and on which an object S to be processed is put; a plasma processing gas introduction pipe 23 through which plasma processing gas is introduced into the plasma processing chamber 21; and an exhaust pipe 24 through which gas in the plasma processing chamber 21 is discharged. The internal space of the plasma processing chamber 21 corresponds to the above-described plasma processing space. The plasma processing gas introduction pipe 23 is used, for example, in supplying source gas that is a source of a thin film in a case where molecules of the source gas are decomposed by plasma and deposited on the object (a substrate) S. For example, in a case where the object S is directly etched by plasma from the plasma source 10, the plasma processing gas introduction pipe 23 can be eliminated.

In this plasma processing apparatus 20, first, gas (air) in the plasma processing chamber 21 is discharged through the exhaust pipe 24 by using a vacuum pump (not shown), and, if necessary, predetermined gas is supplied into the plasma processing chamber 21 through the plasma processing gas introduction pipe 23. Then, by causing the plasma source 10 to operate as described above, plasma is introduced into the plasma processing chamber 21 through the opening 12, and processes, such as deposition of a thin film material and etching, are performed on the object S.

The example of the plasma source 10 used in the plasma processing apparatus is described here; however, the above-described plasma source 10A may be used. Accordingly, if the plasma source 10A is used, plasma can be supplied into a plasma processing chamber through the slit-like opening 12, and the processes, such as deposition of a thin film material and etching, can be performed on a long object to be processed.

The present invention is not limited to the above-described embodiments.

For example, the shape of the radio-frequency antenna 13 can be various shapes of which the number of turns is one or less, such as a partially circular shape like a semicircle and a rectangular shape, besides the above-described U-shape.

Furthermore, the radio-frequency antenna 13 may be provided outside the plasma generation chamber 11, or may be provided inside the wall 111. In those cases, there is no need to provide the protection tube 131 around the radio-frequency antenna 13, and it is possible to use a dielectric in the wall 111.

The magnitude and frequency of the radio-frequency power supplied from the first radio-frequency power source 161 to the radio-frequency antenna 13 or from the second radio-frequency power source 162 between the voltage application electrodes 14 and the magnitude of a potential applied from the direct-current power source 163 to the acceleration electrode 16 are all not limited to those described above. Moreover, instead of the radio-frequency voltage, a direct current voltage may be applied to the voltage application electrodes 14.

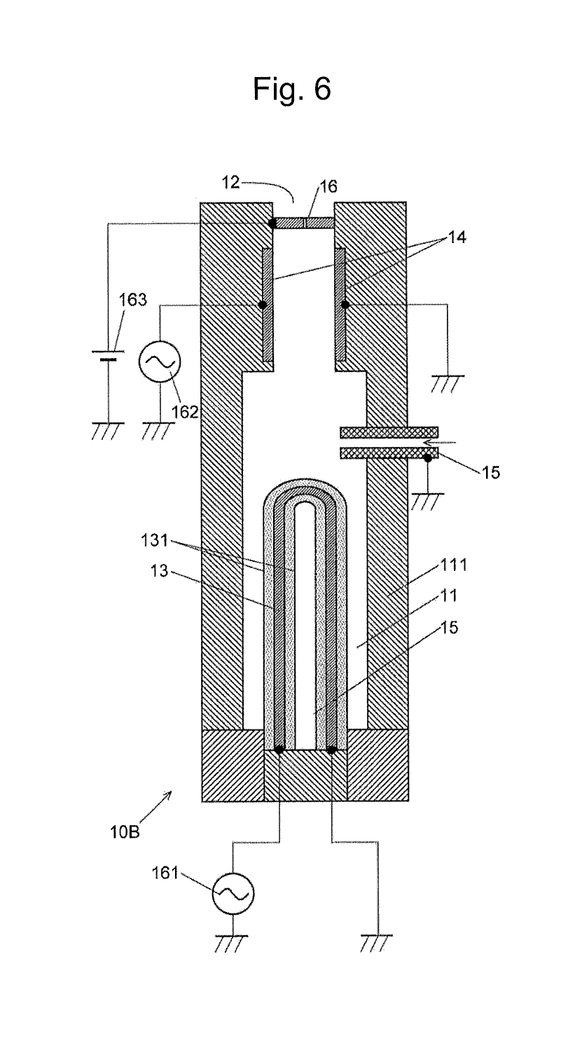

A distal end 151 of the gas supply pipe 15 may be provided closer to the side opposite to the opening 12 than the voltage application electrodes 14. For example, the opening 151 may be provided in a position closer to the side of the opening 12 than the radio-frequency antenna 13, just like a plasma source 10B shown in FIG. 6.

The acceleration electrode 16 is provided closer to the side of the opening 12 than the voltage application electrodes 14. For example, the acceleration electrode 16 may be provided inside the plasma generation chamber 11 as shown in FIG. 6. The number of holes provided on the acceleration electrode 16 may be multiple as described above, or may be only one. Moreover, plasma spontaneously flowing into the plasma processing space through the opening may be used without providing the acceleration electrode 16.

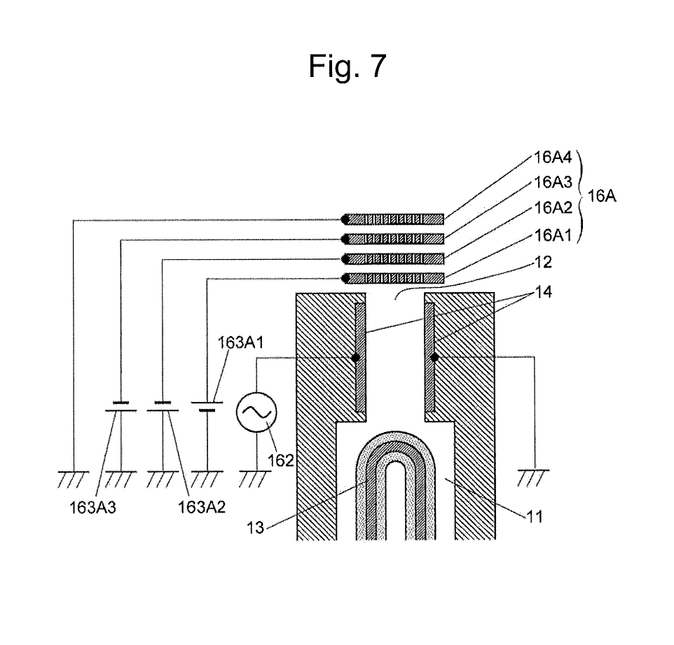

As shown in FIG. 7, an acceleration electrode composed of a plurality of electrodes may be provided on the side of the opening 12. This example employs an acceleration electrode 16A composed of four electrodes, i.e., first to fourth acceleration electrodes 16A1 to 16A4 in order from the side close to the opening 12. The first acceleration electrode 16A1 is applied with a positive potential required for acceleration of positive ions by a first direct-current power source 163A1. The second acceleration electrode 16A2 is applied with a negative potential of opposite polarity of the first acceleration electrode 16A1 to adjust a sheath shape of plasma by a second direct-current power source 163A2. The third acceleration electrode 16A3 is applied with a negative potential of the same polarity as the second acceleration electrode 16A2 to adjust the spread of a beam by a third direct-current power source 163A3. The fourth acceleration electrode 16A4 is set at a ground potential.

Needless to say, any of the above-described modification examples of the plasma source can be used as a plasma source in the plasma processing apparatus.

### REFERENCE SIGNS LIST

10, 10A, 10B . . . Plasma Source
11 . . . Plasma Generation Chamber
111 . . . Wall of Plasma Generation Chamber
12 . . . Opening
13 . . . Radio-frequency Antenna
131 . . . Protection Tube
14 . . . Voltage Application Electrode
15 . . . Gas Supply Pipe
151 . . . Distal End of Gas Supply Pipe
16 . . . Acceleration Electrode
161 . . . First Radio-frequency Power Source
162 . . . Second Radio-frequency Power Source
163 . . . Direct-current Power Source
163A1 . . . First Direct-current Power Source
163A2 . . . Second Direct-current Power Source
163A3 . . . Third Direct-current Power Source
21 . . . Plasma Processing Chamber
22 . . . Object Stand
23 . . . Plasma Processing Gas Introduction Pipe
24 . . . Exhaust Pipe
S . . . Object to be Processed

1. A plasma source that is a device for supplying plasma to a plasma processing space in which a process using the plasma is performed, the plasma source comprising:
a) a plasma generation chamber;
b) an opening that allows the plasma generation chamber to communicate with the plasma processing space;
c) a radio-frequency antenna that is a coil of less than one turn provided in a position where a radio-frequency electromagnetic field having predetermined strength required to generate plasma is able to be generated in the plasma generation chamber;
d) voltage application electrodes provided in a position close to the opening in the plasma generation chamber; and
e) a gas supply unit that supplies plasma source gas to a position closer to a side opposite to the opening than the voltage application electrodes in the plasma generation chamber.

2. The plasma source according to claim 1, wherein a radio-frequency power source that applies a radio-frequency voltage is connected to the voltage application electrodes.

3. The plasma source according to claim 2, wherein the radio-frequency voltage has a frequency in a range of 10 MHz to 100 MHz.

4. The plasma source according to claim 1, further comprising an acceleration electrode having a hole; the acceleration electrode is provided outside the plasma generation chamber in a position facing the opening, or inside the plasma generation chamber in a position closer to a side of the opening than the voltage application electrodes.

5. A plasma processing apparatus comprising:
the plasma source according to claim 1; and
a plasma processing chamber whose inside is the plasma processing space.

6. The plasma source according to claim 2, further comprising an acceleration electrode having a hole; the acceleration electrode is provided outside the plasma generation chamber in a position facing the opening, or inside the plasma generation chamber in a position closer to a side of the opening than the voltage application electrodes.

7. The plasma source according to claim 3, further comprising an acceleration electrode having a hole; the acceleration electrode is provided outside the plasma generation chamber in a position facing the opening, or inside the plasma generation chamber in a position closer to a side of the opening than the voltage application electrodes.

8. A plasma processing apparatus comprising:
the plasma source according to claim 2; and
a plasma processing chamber whose inside is the plasma processing space.

9. A plasma processing apparatus comprising:
the plasma source according to claim 3; and
a plasma processing chamber whose inside is the plasma processing space.

10. A plasma processing apparatus comprising:
the plasma source according to claim 4; and
a plasma processing chamber whose inside is the plasma processing space.

11. A plasma processing apparatus comprising:
the plasma source according to claim 6; and
a plasma processing chamber whose inside is the plasma processing space.

12. A plasma processing apparatus comprising:
the plasma source according to claim 7; and
a plasma processing chamber whose inside is the plasma processing space.
